(19) United States
(12) Patent Application Publication
(10) Pub. No.: US 2025/0391739 A1
(43) Pub. Date: Dec. 25, 2025

(54) DUAL-LINER THROUGH-SILICON VIA (TSV) FOR POWER AND SIGNAL TRANSMISSION

(71) Applicant: QUALCOMM Incorporated, San Diego, CA (US)

(72) Inventors: Mustafa BADAROGLU, San Diego, CA (US); Zhongze WANG, San Diego, CA (US); Woo Tag KANG, San Diego, CA (US); Jihong CHOI, San Diego, CA (US); Hyun LEE, San Diego, CA (US); Giridhar NALLAPATI, San Diego, CA (US); Periannan CHIDAMBARAM, San Diego, CA (US)

(21) Appl. No.: 18/773,389

(22) Filed: Jul. 15, 2024

Related U.S. Application Data
(60) Provisional application No. 63/662,357, filed on Jun. 20, 2024.

(51) Int. Cl. H01L 23/48; H01L 21/768; H01L 25/065; H10B 80/00

(52) U.S. Cl. CPC H01L 23/481; H01L 21/76831; H01L 21/76879; H01L 21/76898; H01L 25/0657; H10B 80/00

(57) ABSTRACT

A 3D stacked chip is described. The 3D stacked chip includes a first die and a second die stacked on the first die. The 3D stacked chip also includes a first through-silicon via (TSV) extending through the second die and landing on the first die. The first TSV is composed of a conductive inner layer and a dielectric liner having a first liner thickness. The 3D stacked chip further includes a second TSV extending through the second die landing on the first die. The second TSV is composed of a conductive inner layer and a dielectric liner having a second liner thickness different from the first liner thickness.

### CROSS-REFERENCE TO RELATED APPLICATION

The present application claims the benefit of U.S. Provisional Patent Application No. 63/662,357, filed Jun. 20, 2024, and titled “DUAL-LINER THROUGH-SILICON VIA (TSV) FOR POWER AND SIGNAL TRANSMISSION,” the disclosure of which is expressly incorporated by reference herein in its entirety.

### BACKGROUND

### Field

Aspects of the present disclosure relate to semiconductor devices and, more particularly, to a dual-liner through-silicon via (TSV) for power and signal transmission.

### Background

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has increased due to the considerable number of devices that are now interconnected in a modern electronic device. The increased number of interconnect levels for supporting the increased number of devices involves more intricate processes.

In practice, a high-capacitance through-silicon via (TSV) (Ctsv) incurs a significant energy/bit penalty (e.g., Ctsv*voltage (V)²) as well as a significant performance penalty (e.g., Rdrv*Ctsv) for signal line transmission. As described, Rdrv refers to a driving resistance of an IO/buffer that drives the TSV. Additionally, V is a peak-to-peak voltage of signal transmitted through the TSV. Conversely, a high-resistance TSV (Rtsv) incurs a significant power distribution network (PDN) integrity penalty for power line transmission. One solution for reducing capacitance in TSVs involves utilizing an increased oxide liner thickness. Unfortunately, this solution results in a higher-resistance TSV due to the reduction of metal diameter in the TSV for accommodating the increased oxide liner thickness. Additionally, reducing resistance in the TSV utilizing a reduced oxide liner thickness increases the TSV capacitance. A via solution that is improved or even optimized for concurrent signaling and power distribution is desired.

### SUMMARY

A 3D stacked chip is described. The 3D stacked chip includes a first die and a second die stacked on the first die. The 3D stacked chip also includes a first through-silicon via (TSV) extending through the second die and landing on the first die. The first TSV is composed of a conductive inner layer and a dielectric liner having a first liner thickness. The 3D stacked chip further includes a second TSV extending through the second die landing on the first die. The second TSV is composed of a conductive inner layer and a dielectric liner having a second liner thickness different from the first liner thickness.

A method for forming dual-liner vias is described. The method includes depositing a first dielectric liner layer in a first via opening and a second via opening, the first dielectric liner layer having a first liner thickness. The method also includes forming an oxide plug in the second via opening. The method further includes depositing a second dielectric liner layer in the first via opening, the second dielectric liner layer having a second liner thickness different from the first liner thickness. The method also includes removing the oxide plug from the second via opening to expose the first dielectric liner layer. The method further includes plating a conductive material on the second dielectric liner layer in the first via opening and the first dielectric liner layer in the second via opening to form a first through-silicon via (TSV) and a second TSV.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), including stacked integrated circuit (IC) dies, having a dual-liner through-silicon via (TSV) for power and signal transmission, in accordance with certain aspects of the present disclosure.

FIGS. 2A-2C illustrate a perspective view and cross-section views of three-dimensional (3D) stacked integrated circuit (IC) dies, having a dual-liner through-silicon via (TSV) for power and signal transmission over cross-tier interconnect connections, according to various aspects of the present disclosure.

FIGS. 3A-3J are block diagrams illustrating a dual-liner through-silicon via (TSV) formation process for signal TSVs and power TSV-bundles of the 3D stacked IC shown in FIGS. 2A-2C, according to various aspects of the present disclosure.

FIG. 4 is a process flow diagram illustrating a method for forming a dual-liner through-silicon via (TSV), according to various aspects of the present disclosure.

FIG. 5 is a block diagram showing an exemplary wireless communications system in which a configuration of the disclosure may be advantageously employed.

FIG. 6 is a block diagram illustrating a design workstation used for circuit, layout, and logic design of a semiconductor component, according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches, repeaters, and/or buffers. As described herein, the term “proximate” used throughout this description means “adjacent, very near, next to, or close to.” As described herein, the term “on” used throughout this description means “directly on” in some configurations, and “indirectly on” in other configurations. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably.

A system hierarchy includes interconnection of active devices at a lowest system level all the way up to system level interconnections at a highest level. Electrical connections exist at each of the levels of the system hierarchy to connect different devices together on an integrated circuit. As integrated circuits become more complex, however, more interconnect layers are used to provide the electrical connections between the devices. More recently, the number of interconnect levels for circuitry has increased due to the substantial number of devices that are now interconnected in a modern electronic device.

Three-dimensional (3D) integration involves a multi-wafer (e.g., N>2) stacking capability, especially for enabling high-capacity memory (e.g., dynamic random-access memory (DRAM)). In practice, through-silicon via (TSV) technology for supporting multi-wafer stacking involves a co-development of advanced processes with the TSV process leading to delay in the technology introduction. Additionally, the 3D integration for multi-wafer stacking capability involves TSVs suitable for both signal transmission as well as power transmission. Unfortunately, a unique solution for a TSV that is improved or even optimized for concurrent signaling distribution and power distribution remains elusive.

In practice, a high-capacitance TSV (Ctsv) incurs a significant energy/bit penalty (e.g., Ctsv*V²) as well as a significant performance penalty (e.g., Rdrv*Ctsv) for signal line transmission. As described, Rdrv refers to a driving resistance of an IO/buffer that drives the TSV. Additionally, V is a peak-to-peak voltage of signal transmitted through the TSV. Conversely, a high-resistance TSV (Rtsv) incurs a significant power distribution network (PDN) integrity penalty for power line transmission. One solution for reducing capacitance in TSVs involves utilizing an increased oxide liner thickness. Unfortunately, this solution results in a higher-resistance TSV due to the reduction of metal diameter in the TSV for accommodating the increased oxide liner thickness. Additionally, reducing resistance in the TSV utilizing a reduced oxide liner thickness increases the TSV capacitance. A via solution that is improved or even optimized for concurrent signaling and power distribution is desired.

Various aspects of the present disclosure provide a dual-liner through-silicon via (TSV) for power and signal transmission. A process flow for fabrication of integrated circuit (IC) dies having a dual-liner TSV for power and signal transmission may include front-end-of-line (FEOL) processes, middle-of-line (MOL) processes, and back-end-of-line (BEOL) processes. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably.

Various aspects of the present disclosure introduce a through-silicon via (TSV) integration scheme that allows both low-capacitance TSVs (e.g., signaling TSVs) and low-resistance TSVs (e.g., a power TSV-bundle) on a logic die/memory die. According to various aspects of the present disclosure, TSVs with a thicker oxide liner enable higher performance and more energy-efficient signaling on the signaling TSVs because of their lower capacitance. Additionally, TSVs with a thinner oxide liner enable a lower current (I) resistance (R) (IR) drop on the power TSVs because of the lower resistance. In some implementations, the thinner oxide beneficially enables higher capacitance, which can be utilized as an embedded de-capacitor on the TSV. According to various aspects of the present disclosure, a via solution that is improved or even optimized for concurrent signaling and power distribution may be fabricated utilizing a low-cost TSV integration scheme (e.g., common metallization, chemical mechanical polish (CMP), and TSV reveal steps) enabling dual-liner TSVs.

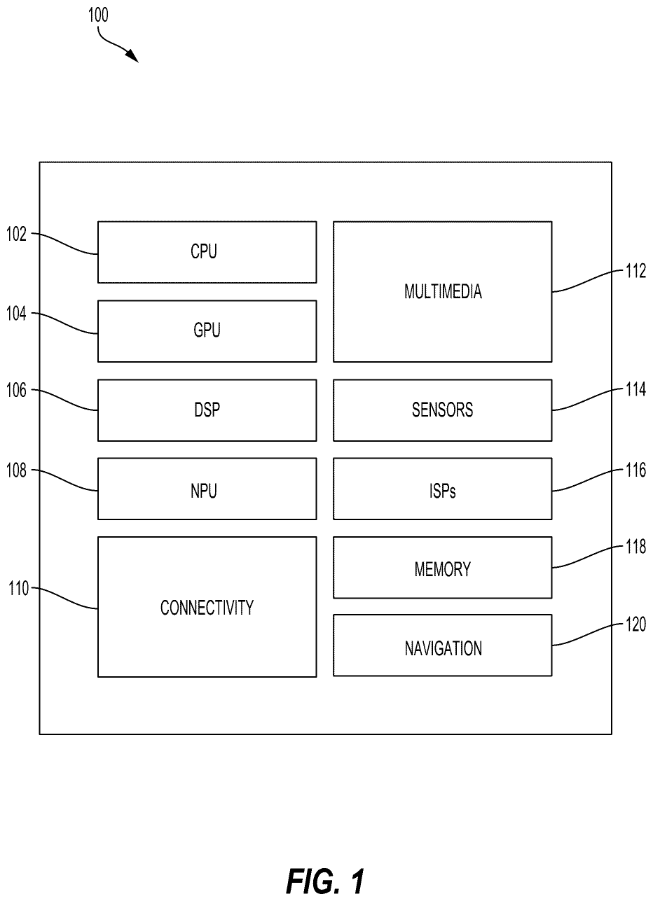

FIG. 1 illustrates an example implementation of a host system-on-chip (SoC) 100, which includes stacked integrated circuit (IC) dies, having a dual-liner through-silicon via (TSV) for concurrent power and signal transmission, in accordance with aspects of the present disclosure. The host SoC 100 includes processing blocks tailored to specific functions, such as a connectivity block 110. The connectivity block 110 may include sixth generation (6G), connectivity, fifth generation (5G) new radio (NR) connectivity, fourth generation long term evolution (4G LTE) connectivity, WI-FI connectivity, universal serial bus (USB) connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

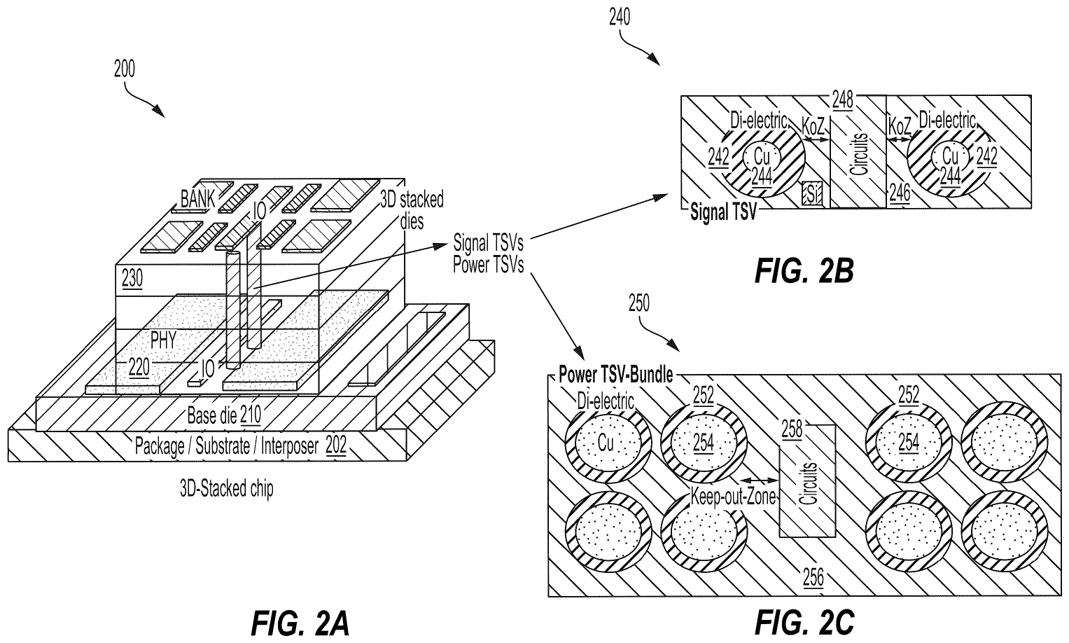

Three-dimensional (3D) integration involves a muti-wafer (e.g., N>2) stacking capability, especially for enabling high-capacity memory (c.g., dynamic random-access memory (DRAM)). In practice, the 3D integration for multi-wafer stacking capability involves TSVs suitable for both signal transmission as well as power transmission. Unfortunately, a unique solution for a TSV that is improved or even optimized for concurrent signaling distribution and power distribution remains elusive. Various aspects of the present disclosure are directed to a dual-liner TSV for power and signal transmission in cross-tier interconnect connection of multi-stack dies, for example, as shown in FIGS. 2A-2C.

FIGS. 2A-2C illustrate a perspective view and cross-section views of stacked integrated circuit (IC) dies, having a dual-liner through-silicon via (TSV) for power and signal transmission over cross-tier interconnect connections, according to various aspects of the present disclosure. As shown in FIG. 2A, a 3D stacked chip 200 includes a base die 210 (e.g., a first die) that is supported by a package substrate 202. In various aspects of the present disclosure, the base die 210 supports a stack of memory dies 230 (c.g., two (2) or more dynamic random-access memory (DRAM) dies) on the base die 210. In this example, the memory dies 230 include memory banks (BANK) and an input/output (IO) block that utilize vias (e.g., TSVs) extending through the memory dies 230 (e.g., second die) and landing on the base die 210 to enable power and signal transmission between the memory dies 230 and a physical layer (PHY) 220 of the base die 210.

As noted above, a high-capacitance TSV (Ctsv) incurs a significant energy/bit penalty (c.g., Ctsv*V²) as well as a significant performance (c.g., 1/(Rdrv*Ctsv)) and power penalty (e.g., Ctsvs*Vtsv²*frequency) for signal line transmission. Conversely, a high-resistance TSV (Rtsv) incurs a significant power distribution network (PDN) integrity penalty for power line transmission. One solution for reducing capacitance in TSVs involves utilizing an increased oxide liner thickness. Unfortunately, this solution results in a higher-resistance TSV due to the reduction of metal diameter in the TSV for accommodating the increased oxide liner thickness. Additionally, reducing resistance in the TSV utilizing a reduced oxide liner thickness increases the TSV capacitance.

As shown in FIGS. 2A-2C, signal TSVs 240 and power TSV-bundles 250 occupy the same unit TSV area; however, the thickness of a dielectric liner layer 242/252 and the diameter of a conductive inner layer 244/254 are varied. In practice, the power TSV-bundles 250 are configured (e.g., 1×2, 2×2, m×n) to deliver larger current (e.g., ˜30 mA/TSV). Although reduction of the thickness of the dielectric liner layer 242/252 (e.g., an oxide-liner thickness) reduces a TSV resistance, a larger capacitance and increased keep out zone (KoZ) distance (e.g., ˜2× TSV diameter) mitigates mechanical stress induced current variation on a transistor placed nearby the TSV.

Array efficiency is significantly impacted in smaller DRAM bank-tiles due to the increased KoZ distance (e.g., ˜8% of block dimension overhead). Additionally, TSVs consume a sizable portion (e.g., 40%) of energy/bit to transfer data bit from a DRAM bank to a pin of the base die 210. According to various aspects of the present disclosure, the 3D stacked chip 200 utilizes a via solution that is improved or even optimized for concurrent signaling and power distribution, as further illustrated in FIGS. 2B and 2C.

FIG. 2B illustrates signal through-silicon vias (TSVs), according to various aspects of the present disclosure. As shown in FIG. 2B, signal TSVs 240 are configured with a thicker dielectric liner layer 242 and a reduced diameter, conductive inner layer 244. This configuration of the signal TSVs 240 exhibits a reduced capacitance, as well as higher performance and a lower energy/bit. Additionally, this configuration of the signal TSVs 240 results in a reduced keep out zone (KoZ) distance between the signal TSVs 240 and logic circuits 248 in a semiconductor layer 246 (e.g., silicon). The reduced KoZ distance beneficially supports improved circuit density by utilizing better area efficiency.

As shown in FIG. 2C, the power TSV-bundles 250 are configured with the reduced thickness, dielectric liner layer 252. The reduced thickness of the dielectric liner layer 252 results in an increased diameter of the conductive inner layer 254, as a TSV diameter of the power TSV-bundles 250 is maintained. This configuration of the power TSV-bundles 250 exhibits a higher (e.g., improved) decoupling capacitance. Additionally, the increased diameter of the conductive inner layer 254 of the power TSV-bundles 250 results in a reduced KoZ distance between the signal TSVs 240 and logic circuits 258 in a semiconductor layer 256 (e.g., silicon).

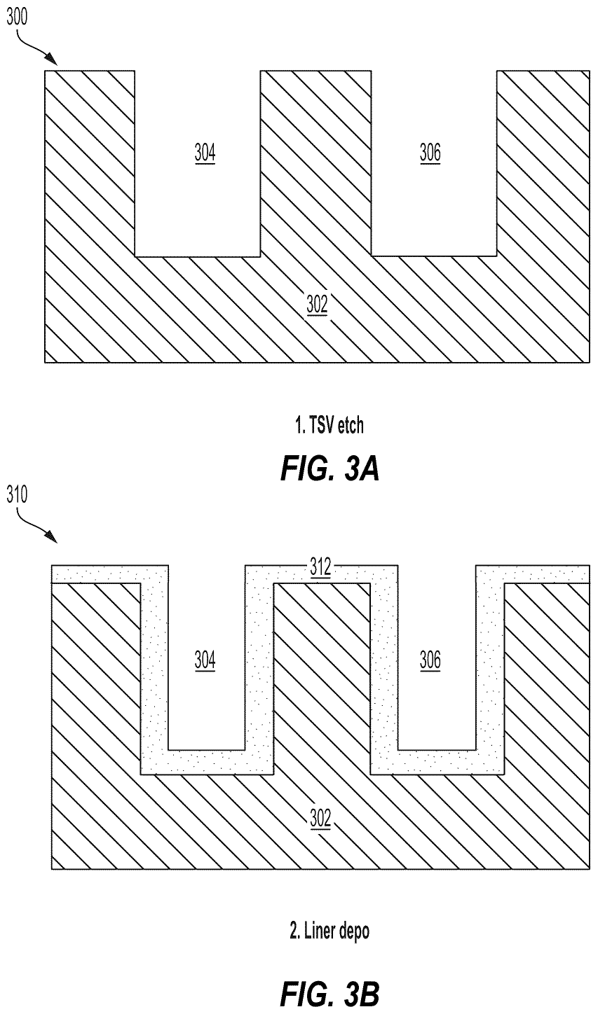

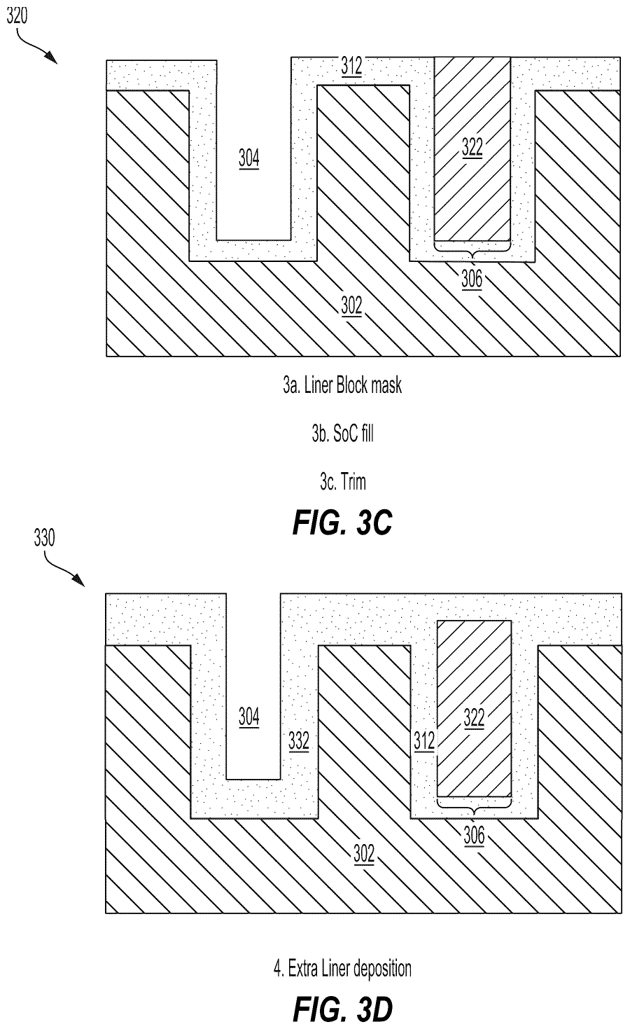

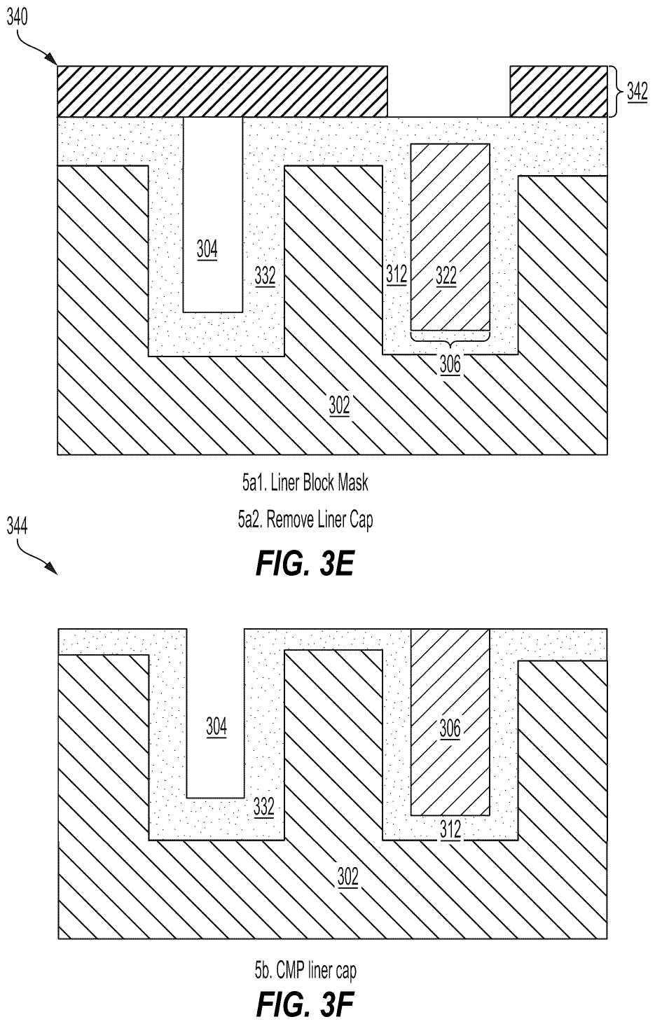

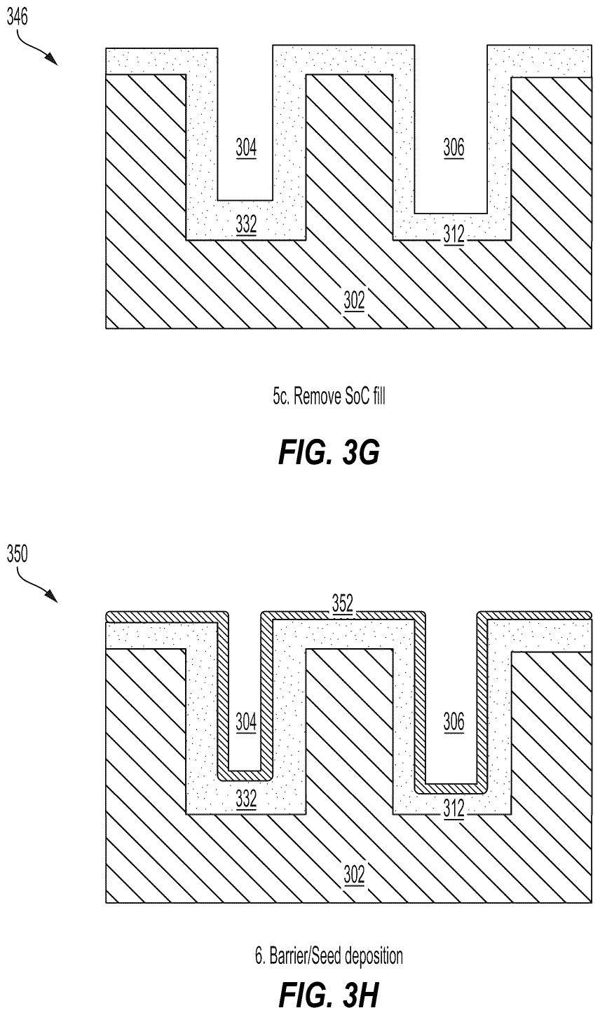

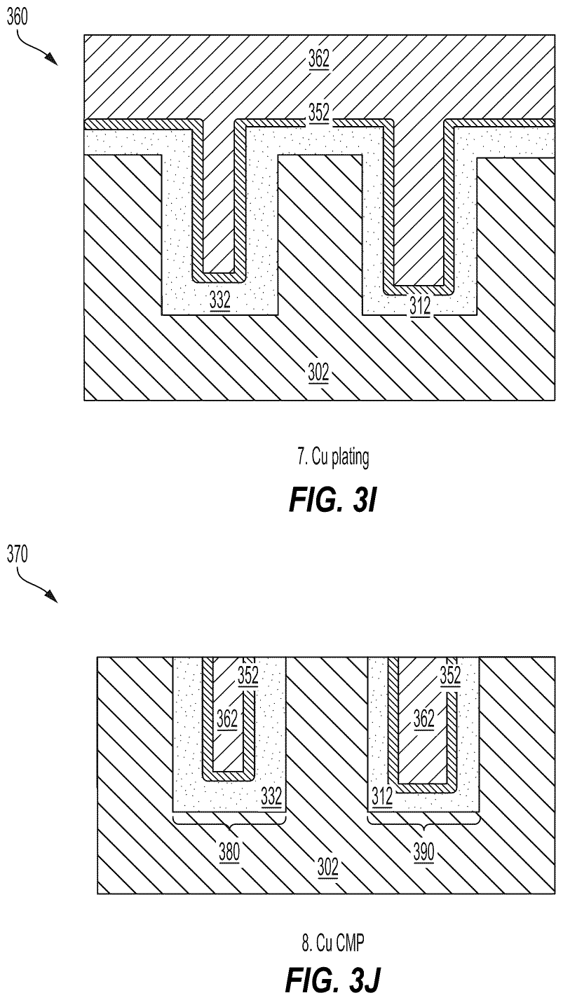

According to various aspects of the present disclosure, the increased diameter of the conductive inner layer 254 provides reduced resistance as well as a lower IR drop. This reduced resistance as well as the lower IR drop due to the increased diameter of the conductive inner layer 254 beneficially supports improved area density by utilizing a reduced number of TSVs in the power TSV-bundles 250. Additionally, the reduced number of TSVs in the power TSV-bundles 250 improves energy/bit consumption, which leads to higher performance operation. One implementation of a process for enabling dual-line TSVs in the same die is shown in FIGS. 3A-3J.

FIGS. 3A-3J are block diagrams illustrating a dual-liner through-silicon via (TSV) formation process for the signal TSVs 240 and the power TSV-bundles 250 of the 3D stacked chip 200 shown in FIGS. 2A-2C, according to various aspects of the present disclosure.

As shown in FIG. 3A, a dual-liner TSV formation process begins at step 300, in which a TSV etch is performed in a substrate 302 (e.g., a silicon or other like semiconductor substrate material) to form openings 304 and 306. In various aspects of the present disclosure, the openings 304 and 306 having matching dimensions (e.g., a four (4) micron diameter).

As shown in FIG. 3B, at step 310, a dielectric liner deposition defines a first dielectric liner layer 312 on the sidewalls and base of the openings 304 and 306. In this example, the first dielectric liner layer 312 is uniformly deposited to provide a predetermined first thickness to enable formation of the power TSV-bundles 250, for example, as shown in FIG. 2C. In some implementations, the first dielectric liner thickness is selected below a predetermined value (e.g., one (1) micron) to allow a larger inner TSV diameter for better TSV resistance.

As shown in FIG. 3C, at step 320, a liner block mask is formed over the opening 304 and a spin-on-carbon 322 (e.g., an oxide plug or other like cavity block layer, such as an amorphous silicon polymer) fills the opening 306. Next, a trim process exposes the first dielectric liner layer 312. In various aspects of the present disclosure, the spin-on-carbon 322 operates as a liner block to maintain the thickness of the first dielectric liner layer 312 on the base and sidewalls of the opening 306.

As shown in FIG. 3D, at step 330, an extra liner deposition enables formation of a second dielectric liner 332. In this example, the second dielectric liner 332 is uniformly deposited to provide a predetermined second thickness to enable formation of the signal TSVs 240, for example, as shown in FIG. 2B. Additionally, the spin-on-carbon 322 maintains the thickness of the first dielectric liner layer 312 on the base and sidewalls of the opening 306, while the second dielectric liner 332 reduces a diameter of the opening 304. In this example, a portion of the extra liner deposition forms an oxide cap on the spin-on-carbon 322 in the opening 306. In some implementations, a predetermined second thickness of the second dielectric liner 332 is selected for an increased thickness (e.g., greater than one (1) micron) according to a limit allowed for the metal filling capability of high-aspect ratio TSVs.

As shown in FIG. 3E, at step 340, an optional, liner block mask is formed over the opening 304. Next, the liner cap on the spin-on-carbon 322 in the opening 306 is removed. As shown in FIG. 3F, at step 344, alternatively, the liner cap is removed by a chemical mechanical polish (CMP) trim without the optional, liner block mask 342 shown in FIG. 3E.

As shown in FIG. 3G, at step 346, the spin-on-carbon 322 is removed to expose the first dielectric liner layer 312 in the opening 306. Removal of the spin-on-carbon 322 as well as the optional, liner block mask 342 (see FIG. 3F) completes formation of the first dielectric liner layer 312 and the second dielectric liner 332 separating the openings 304, 306 from the substrate 302. In this example shown in FIG. 3F, the optional, liner block mask 342 is removed after the spin-on-carbon 322 is removed.

As shown in FIG. 3H, at step 350, a barrier/seed layer 352 is deposited on the first dielectric liner layer 312 and the second dielectric liner 332. The barrier/seed layer 352 may be composed of tantalum (Ta), copper (Cu), or other like conductive material.

As shown in FIG. 3I, at step 360, an electroplating process of a conductive inner layer 362 (e.g., electroplated copper (Cu)) is plated on the barrier/seed layer 352. Although described as being composed of electroplated copper, the conductive inner layer 362 may be composed of other like conductive plating materials.

As shown in FIG. 3J, at step 370, a chemical mechanical polish (CMP) process is performed on the conductive inner layer 362 until a surface of the substrate 302 is exposed. This CMP step and common metal filling provide a planarization signature that is distinct from conventional TSV formation. In some implementations, the planarization signature constitutes a uniform height across the TSVs with different liner thicknesses. In various aspects of the present disclosure, exposure of the surface of the substrate 302 completes formation of a signal TSV 380 and a power TSV 390 to be similar, for example, as shown in FIGS. 2B and 2C.

In some implementations, signal TSV 380 extends through a second memory die and lands on a first memory die of the stack of memory dies 230. The signal TSV 380 is composed of a conductive inner layer 362 and a second dielectric liner 332 having a second liner thickness. Additionally, the power TSV 390 extends through the second memory die and lands on the first memory die of the stack of memory dies 230. The power TSV 390 is composed of a conductive inner layer 362 and a first dielectric liner layer 312 having a first liner thickness different from the second liner thickness.

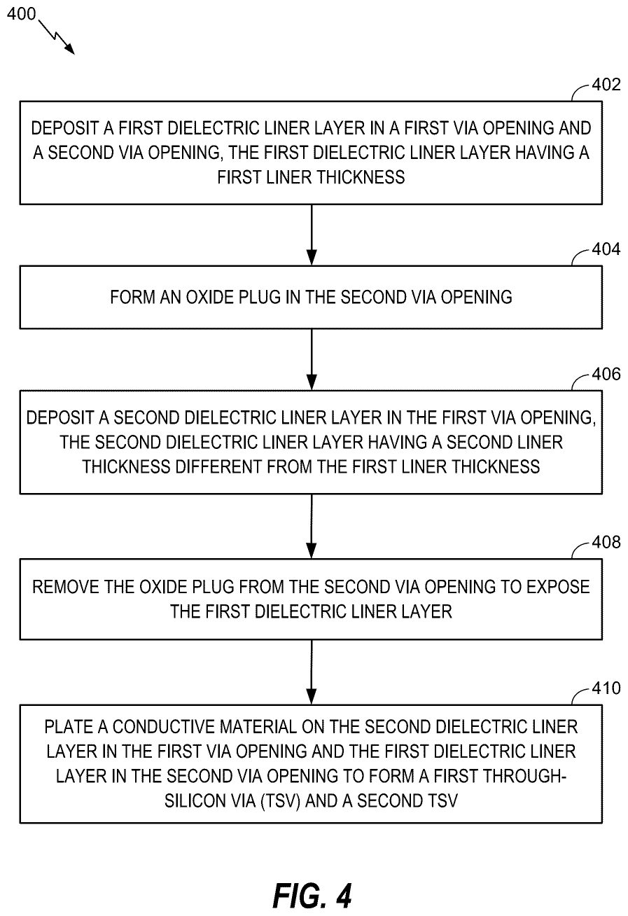

Although FIGS. 3A-3J illustrate a via-middle/via-first process, it should be recognized that the dual-liner via process is applicable to a via-last process. One implementation of a process of forming a dual-liner via is illustrated, for example, in FIG. 4.

FIG. 4 is a process flow diagram illustrating a method 400 for forming a dual-liner through-silicon via (TSV), according to various aspects of the present disclosure. The method 400 begins at block 402, in which a first dielectric liner layer is deposited in a first via opening and a second via opening, the first dielectric liner layer having a first liner thickness. For example, as shown in FIG. 3B a dielectric liner deposition defines a first dielectric liner layer 312 on the sidewalls and base of the openings 304 and 306. In this example, the first dielectric liner layer 312 is uniformly deposited to provide a predetermined first thickness to enable formation of the power TSV-bundles 250, for example, as shown in FIG. 2C. In some implementations, the first dielectric liner thickness is selected below a predetermined value (e.g., one (1) micron) to allow a larger inner TSV diameter for better TSV resistance.

At block 404, an oxide plug is formed in the second via opening. For example, as shown in FIG. 3C, a liner block mask is formed over the opening 304 and a spin-on-carbon 322 (e.g., an oxide plug or other like cavity block layer, such as an amorphous silicon polymer) fills the opening 306. Next, a trim process exposes the first dielectric liner layer 312. In various aspects of the present disclosure, the spin-on-carbon 322 operates as a liner block to maintain the thickness of the first dielectric liner layer 312 on the base and sidewalls of the opening 306.

At block 406, a second dielectric liner layer is deposited in the first via opening, the second dielectric liner layer having a second liner thickness different from the first liner thickness. For example, as shown in FIG. 3D, a second dielectric liner 332 is uniformly deposited to provide a predetermined second thickness to enable formation of the signal TSVs 240, for example, as shown in FIG. 2B. Additionally, the spin-on-carbon 322 maintains the thickness of the first dielectric liner layer 312 on the base and sidewalls of the opening 306, while the second dielectric liner 332 reduces a diameter of the opening 304.

At block 408, the oxide plug is removed from the second via opening to expose the first dielectric liner layer. For example, as shown in FIG. 3G, the spin-on-carbon 322 is removed to expose the first dielectric liner layer 312 in the opening 306. Removal of the spin-on-carbon 322 completes formation of the first dielectric liner layer 312 and the second dielectric liner 332 separating the openings 304, 306 from the substrate 302.

At block 410, a conductive material is plated on the second dielectric liner layer in the first via opening and the first dielectric liner layer in the second via opening to form a first through-silicon via (TSV) and a second TSV. For example, as shown in FIG. 31, an electroplating process of a conductive inner layer 362 (e.g., electroplated copper (Cu)) is plated on the barrier/seed layer 352. Although described as being composed of electroplated copper, the conductive inner layer 362 may be composed of other like conductive plating materials. As shown in FIG. 3J, at step 370, a chemical mechanical polish (CMP) process is performed on the conductive inner layer 362 until a surface of the substrate 302 is exposed. Exposure of the surface of the substrate 302 completes formation of a signal TSV 380 (e.g., first TSV) and a power TSV 390 (c.g., second TSV), for example, as shown in FIGS. 2B and 2C.

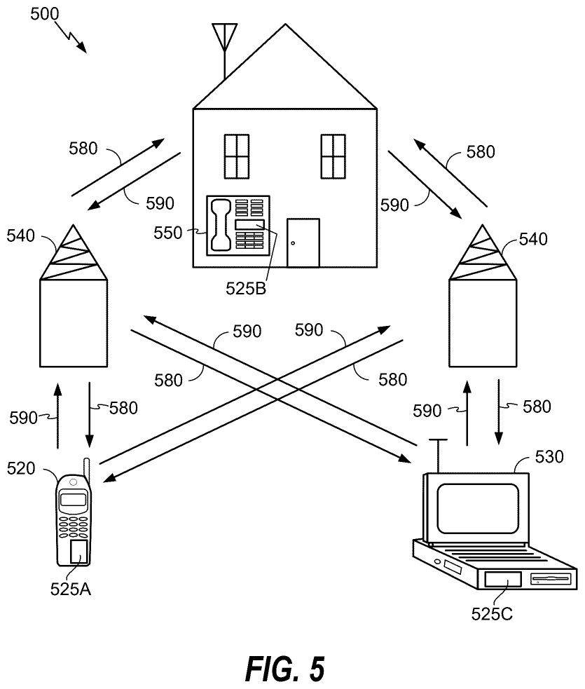

FIG. 5 is a block diagram showing an exemplary wireless communications system 500 in which an aspect of the disclosure may be advantageously employed. For purposes of illustration, FIG. 5 shows three remote units 520, 530, and 550, and two base stations 540. It will be recognized that wireless communications systems may have many more remote units and base stations. Remote units 520, 530, and 550 include integrated circuit (IC) devices 525A, 525C, and 525B that include the disclosed 3D stacked chip, having dual-liner vias to provide signal TSVs and power TSVs. It will be recognized that other devices may also include the disclosed stacked IC dies having dual-liner vias to provide signal TSVs and power TSVs, such as the base stations 540, switching devices, and network equipment. FIG. 5 shows forward link signals 580 from the base stations 540 to the remote units 520, 530, and 550, and reverse link signals 590 from the remote units 520, 530, and 550 to base stations 540.

In FIG. 5, remote unit 520 is shown as a mobile telephone, remote unit 530 is shown as a portable computer, and remote unit 550 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 5 illustrates remote units according to aspects of the present disclosure, the disclosure is not limited to these exemplary illustrated units. Aspects of the present disclosure may be suitably employed in many devices, which include the disclosed vias.

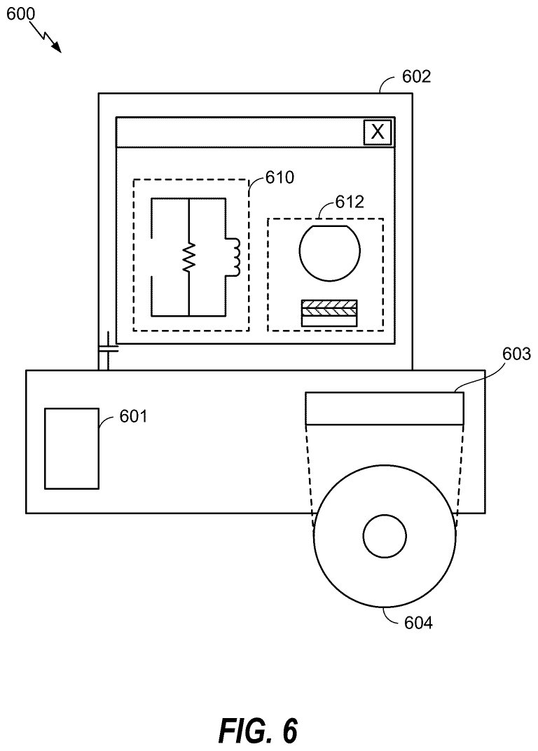

FIG. 6 is a block diagram illustrating a design workstation used for circuit, layout, and logic design of a semiconductor component, such as the 3D stacked chip having dual-liner vias to provide signal TSVs and power TSVs, as disclosed above. A design workstation 600 includes a hard disk 601 containing operating system software, support files, and design software such as Cadence or OrCAD. The design workstation 600 also includes a display 602 to facilitate design of a circuit 610 or an integrated circuit (IC) component 612, such as a 3D stacked chip having dual-liner vias to provide signal TSVs and power TSVs. A storage medium 604 is provided for tangibly storing the design of the circuit 610 or the IC component 612 (e.g., the 3D stacked chip having dual-liner vias to provide signal TSVs and power TSVs). The design of the circuit 610 or the IC component 612 may be stored on the storage medium 604 in a file format such as GDSII or GERBER. The storage medium 604 may be a CD-ROM, DVD, hard disk, flash memory, or other appropriate device. Furthermore, the design workstation 600 includes a drive apparatus 603 for accepting input from or writing output to the storage medium 604.

Data recorded on the storage medium 604 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 604 facilitates the design of the circuit 610 or the IC component 612 by decreasing the number of processes for designing semiconductor wafers.

Implementation examples are described in the following numbered clauses:
1. A 3D stacked chip, comprising:
a first die;
a second die stacked on the first die;
a first through-silicon via (TSV) extending through the second die and landing on the first die, the first TSV comprising a conductive inner layer and a dielectric liner having a first liner thickness; and
a second TSV extending through the second die landing on the first die, the second TSV comprising a conductive inner layer and a dielectric liner having a second liner thickness different from the first liner thickness.
2. The 3D stacked chip of clause 1, in which a diameter of the first TSV equals the diameter of the second TSV.
3. The 3D stacked chip of any of clauses 1 or 2, in which the first TSV comprises a signal TSV and the second TSV comprises a power TSV.
4. The 3D stacked chip of clause 3, in which a diameter of the conductive inner layer of the signal TSV is less than the first liner thickness.
5. The 3D stacked chip of clause 3, in which a diameter of the conductive inner layer of the power TSV is greater than the second liner thickness.
6. The 3D stacked chip of clause 3, in which the power TSV comprises a power TSV-bundle.
7. The 3D stacked chip of clause 3, in which a keep out zone of the power TSV is greater than a keep out zone of the signal TSV.
8. The 3D stacked chip of any of clauses 1-7, in which the dielectric liner of the first TSV comprises a dielectric liner and the conductive inner layer of the first TSV comprises copper having a barrier/seed layer between the copper and the dielectric liner of the first TSV.
9. The 3D stacked chip of any of clauses 1-8, in which the dielectric liner of the second TSV comprises a dielectric liner and the conductive inner layer of the second TSV comprises copper having a barrier/seed layer between the copper and the dielectric liner of the first TSV.
10. The 3D stacked chip of any of clauses 1-9, in which the first die comprises a base die and the second die is part of a stack of memory dies.
11. A method for forming dual-liner vias, the method comprising:
depositing a first dielectric liner layer in a first via opening and a second via opening, the first dielectric liner layer having a first liner thickness;
forming an oxide plug in the second via opening;
depositing a second dielectric liner layer in the first via opening, the second dielectric liner layer having a second liner thickness different from the first liner thickness;
removing the oxide plug from the second via opening to expose the first dielectric liner layer; and
plating a conductive material on the second dielectric liner layer in the first via opening and the first dielectric liner layer in the second via opening to form a first through-silicon via (TSV) and a second TSV.
12. The method of clause 11, in which a diameter of the first TSV equals the diameter of the second TSV.
13. The method of any of clauses 11 or 12, in which the first TSV comprises a signal TSV and the second TSV comprises a power TSV.
14. The method of clause 13, in which a diameter of the conductive inner layer of the signal TSV is less than the first liner thickness.
15. The method of clause 13, in which a diameter of the conductive inner layer of the power TSV is greater than the second liner thickness.
16. The method of clause 13, in which the power TSV comprises a power TSV-bundle.
17. The method of clause 13, in which a keep out zone of the power TSV is greater than a keep out zone of the signal TSV.
18. The method of any of clauses 11-17, in which the dielectric liner of the first TSV comprises a dielectric liner and the conductive inner layer of the first TSV comprises copper having a barrier/seed layer between the copper and the dielectric liner of the first TSV.
19. The method of any of clauses 11-18, in which the dielectric liner of the second TSV comprises a dielectric liner and the conductive inner layer of the second TSV comprises copper having a barrier/seed layer between the copper and the dielectric liner of the first TSV.
20. The method of any of clauses 11-19, in which removing the oxide plug comprises:
forming a liner block mask on the first via opening;
removing a liner cap on the oxide plug, and
removing the oxide plug from the second via opening to expose the first dielectric liner layer.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A 3D stacked chip, comprising:
a first die;
a second die stacked on the first die;
a first through-silicon via (TSV) extending through the second die and landing on the first die, the first TSV comprising a conductive inner layer and a dielectric liner having a first liner thickness; and
a second TSV extending through the second die landing on the first die, the second TSV comprising a conductive inner layer and a dielectric liner having a second liner thickness different from the first liner thickness.

2. The 3D stacked chip of claim 1, in which a diameter of the first TSV equals the diameter of the second TSV.

3. The 3D stacked chip of claim 1, in which the first TSV comprises a signal TSV and the second TSV comprises a power TSV.

4. The 3D stacked chip of claim 3, in which a diameter of the conductive inner layer of the signal TSV is less than the first liner thickness.

5. The 3D stacked chip of claim 3, in which a diameter of the conductive inner layer of the power TSV is greater than the second liner thickness.

6. The 3D stacked chip of claim 3, in which the power TSV comprises a power TSV-bundle.

7. The 3D stacked chip of claim 3, in which a keep out zone of the power TSV is greater than a keep out zone of the signal TSV.

8. The 3D stacked chip of claim 1, in which the dielectric liner of the first TSV comprises a dielectric liner and the conductive inner layer of the first TSV comprises copper having a barrier/seed layer between the copper and the dielectric liner of the first TSV.

9. The 3D stacked chip of claim 1, in which the dielectric liner of the second TSV comprises a dielectric liner and the conductive inner layer of the second TSV comprises copper having a barrier/seed layer between the copper and the dielectric liner of the first TSV.

10. The 3D stacked chip of claim 1, in which the first die comprises a base die and the second die is part of a stack of memory dies.

11. A method for forming dual-liner vias, the method comprising:
depositing a first dielectric liner layer in a first via opening and a second via opening, the first dielectric liner layer having a first liner thickness;
forming an oxide plug in the second via opening;
depositing a second dielectric liner layer in the first via opening, the second dielectric liner layer having a second liner thickness different from the first liner thickness;
removing the oxide plug from the second via opening to expose the first dielectric liner layer; and
plating a conductive material on the second dielectric liner layer in the first via opening and the first dielectric liner layer in the second via opening to form a first through-silicon via (TSV) and a second TSV.

12. The method of claim 11, in which a diameter of the first TSV equals the diameter of the second TSV.

13. The method of claim 11, in which the first TSV comprises a signal TSV and the second TSV comprises a power TSV.

14. The method of claim 13, in which a diameter of the conductive inner layer of the signal TSV is less than the first liner thickness.

15. The method of claim 13, in which a diameter of the conductive inner layer of the power TSV is greater than the second liner thickness.

16. The method of claim 13, in which the power TSV comprises a power TSV-bundle.

17. The method of claim 13, in which a keep out zone of the power TSV is greater than a keep out zone of the signal TSV.

18. The method of claim 11, in which the dielectric liner of the first TSV comprises a dielectric liner and the conductive inner layer of the first TSV comprises copper having a barrier/seed layer between the copper and the dielectric liner of the first TSV.

19. The method of claim 11, in which the dielectric liner of the second TSV comprises a dielectric liner and the conductive inner layer of the second TSV comprises copper having a barrier/seed layer between the copper and the dielectric liner of the first TSV.

20. The method of claim 11, in which removing the oxide plug comprises:
forming a liner block mask on the first via opening;
removing a liner cap on the oxide plug, and
removing the oxide plug from the second via opening to expose the first dielectric liner layer.
